(19) United States
(12) Patent Application Publication
(10) Pub. No.: US 2008/0070407 A1
(43) Pub. Date: Mar. 20, 2008

(54) METHOD FOR FORMING A CONDUCTIVE PATTERN IN A SEMICONDUCTOR DEVICE

(75) Inventor: Jae-Hong Kim, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 11/854,542

(22) Filed: Sep. 13, 2007

(30) Foreign Application Priority Data
Sep. 14, 2006 (KR) 10-2006-0089015

(51) Int. Cl. H01L 21/44

(52) U.S. Cl. 438/669; 257/E21.476

(57) ABSTRACT

A method for forming a conductive pattern in a semiconductor device includes providing an insulation layer including a trench, forming a conductive material over the insulation layer to fill in the trench, polishing the conductive material to expose the insulation layer, and cleaning the resultant structure using a cleaning solution.

### CROSS-REFERENCE TO RELATED APPLICATIONS

The present invention claims priority of Korean patent application number 2006-0089015, filed on Sep. 14, 2006, which is incorporated by reference in its entirety.

### BACKGROUND OF THE INVENTION

The present invention relates to a method for fabricating a semiconductor device, and more particularly, to a method for forming a conductive pattern in a semiconductor device using a damascene process. Specifically, the present invention relates to a method for forming a bit line in a flash memory device using a damascene process.

A height difference has increased in a conductive layer or an insulation layer including multiple layers formed over a wafer as the scale of integration and micronization of a semiconductor device increases and a line structure of the semiconductor device becomes multiple-layered.

To remove the height difference of the wafer generated during the manufacturing process, a chemical mechanical polishing (CMP) process combining a chemical removal process with a mechanical removal process was developed by International Business Machines (IBM) Corporation in the late 80's.

A surface of the wafer to be polished and a polishing pad are in contact. The CMP process provides a slurry to the contact portion and moves the wafer and the polishing pad in a relative direction so that uneven portions of the wafer surface are planarized by simultaneous chemical reaction and physical removal. Thus, performance of the CMP process is determined by, e.g., a process condition of a CMP apparatus, a type of the slurry, and a type of the polishing pad.

As stated above, the CMP process is used for the planarization of a height difference generated in a conductive layer or an insulation layer formed in a multiple-layer structure over the wafer as the scale of integration in a semiconductor device increases. The CMP process is also used when forming a metal line or a contact plug connecting upper and lower conductive structures.

Tungsten (W) has become a typical material used for forming a conductive pattern such as a metal line and a contact plug in a process for fabricating a semiconductor device. A damascene process is applied when forming the metal line and the contact plug using tungsten. A tungsten damascene process includes forming a trench defining a line by patterning an insulation layer, filling in the trench with tungsten, and performing a CMP process to remove the tungsten using a slurry until the insulation layer is exposed. After the CMP process is performed, a cleaning process is performed to remove residue and by-products generated during the CMP process.

In general, a NH₄OH solution and hydrogen fluoride (HF) solution are used during the cleaning process. For instance, the cleaning process includes cleaning at a first brush station using a diluted NH₄OH solution, and cleaning at a second brush station using a diluted HF solution.

However, when using two solutions separately during the cleaning process, two baths are required for the two solutions. Therefore, an amount of a cleaner used in a polisher is increased. Also, the polish residue and metal impurities generated during the CMP process may not be removed completely. Therefore, a cleaning process which can increase cleaning efficiency, decrease production costs, and improve efficiency of a polisher is desired.

### SUMMARY OF THE INVENTION

Embodiments of the present invention are directed to a method for forming a conductive pattern of a semiconductor device. The method can increase a cleaning efficiency during a cleaning process performed after a polishing process, decrease production costs, and improve an applicability of polishing equipment.

In accordance with an aspect of the present invention, a method for forming a conductive pattern in a semiconductor device includes providing an insulation layer including a trench. A conductive material is formed over the insulation layer. The conductive material fills in the trench. The conductive material is polished to expose the insulation layer. The polished conductive layer and the exposed insulation layer form a resultant structure. The resultant structure is cleaned using a cleaning solution.

In accordance with another aspect of the invention, a method for forming a conductive pattern in a semiconductor device includes forming an insulation layer over a substrate. A trench is formed in the insulation layer. A conductive material is formed over the insulation layer. The conductive layer fills in the trench. A chemical mechanical polishing is performed on the conductive material to expose the insulation layer. The polished conductive layer and the exposed insulation layer form a resultant structure. The resultant structure is cleaned using a cleaning solution including a buffered oxide etchant (BOE) solution added with an organic acid. The organic acid forms a passivation layer over the resultant structure.

### BRIEF DESCRIPTION OF THE DRAWINGS

FIGS. 1A to 1C illustrate cross-sectional views of a method for forming a conductive pattern in accordance with an embodiment of the present invention.

FIG. 2 illustrates a diagram showing a potential-pH equilibrium of a tungsten-water system.

### DESCRIPTION OF SPECIFIC EMBODIMENTS

Embodiments of the present invention relate to a method for forming a conductive pattern in a semiconductor device.

Referring to the drawings, the illustrated thickness of layers and regions are exaggerated to facilitate explanation. When a first layer is referred to as being “on” a second layer or “on” a substrate, it could mean that the first layer is formed directly on the second layer or the substrate, or it could also mean that a third layer may exist between the first layer and the second layer or between the first layer and the substrate. Furthermore, the same or like reference numerals throughout the various embodiments of the present invention represent the same or like elements in different drawings.

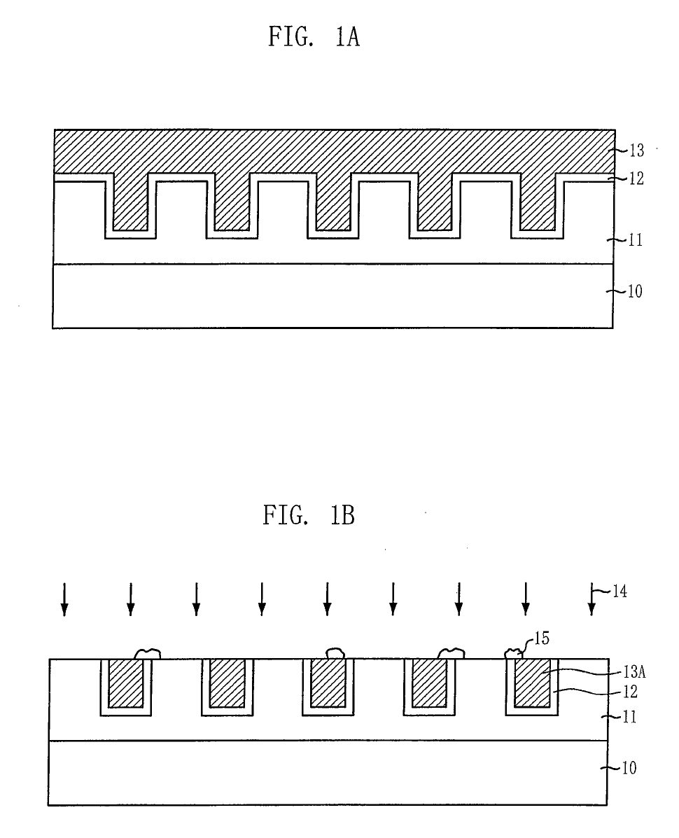

FIGS. 1A to 1C illustrate cross-sectional views of a method for forming a conductive pattern in a semiconductor device in accordance with an embodiment of the present invention. A method for forming a bit line in a flash memory device using a damascene process is described as an example.

Referring to FIG. 1A, a patterned insulation layer 11 is formed over a substrate 10 where transistor formation and impurity doping processes are performed in advance. For instance, the patterned insulation layer 11 includes a high density plasma (HDP) oxide layer formed to a thickness ranging from approximately 2,000 Å to approximately 5,000 Å.

In more detail, a photoresist pattern (not shown) is formed over an insulation layer formed over the substrate 10. A hard mask pattern (not shown) is formed by performing an etch process using the photoresist pattern as an etch mask. The hard mask pattern includes a silicon nitride. For example, the hard mask pattern is formed by forming a silicon nitride layer and etching the silicon nitride layer exposed by the photoresist pattern. The silicon nitride layer is formed using a plasma enhanced chemical vapor deposition (PECVD) method. Detailed conditions of the silicon nitride formation include a pressure ranging from approximately 5 Torr to approximately 10 Torr, a radio frequency (RF) power of approximately 430 W, and a temperature of approximately 550° C. Silicon hydride (SiH₄), ammonia (NH₃), and nitrogen (N₂) gases are supplied as formation gases flowing at a rate ranging from approximately 20 sccm to approximately 100 sccm, from approximately 10 sccm to approximately 50 sccm, and from approximately 4,000 sccm to approximately 5,000 sccm, respectively.

An etch condition for the silicon nitride layer includes maintaining a pressure in an etch chamber ranging from approximately 30 mTorr to approximately 50 mTorr, a RF power ranging from approximately 1,000 W to approximately 2,000 W, and a bias power ranging from approximately 1,500 W to approximately 2,000 W, and using fluoro form (CHF₃), oxygen (O₂), and argon (Ar) gas as an etch gas. The CHF₃ gas flows at a rate ranging from approximately 30 sccm to approximately 50 sccm, the O₂ gas flows at a rate ranging from approximately 10 sccm to approximately 50 sccm, the Ar gas flows at a rate ranging from approximately 500 sccm to approximately 800 sccm, and a temperature in the etch chamber ranges from approximately 40° C. to approximately 60° C.

A plurality of trenches (not shown) is formed in the insulation layer by etching portions of the insulation layer exposed by the hard mask pattern. Thus, the patterned insulation layer 11 is formed.

The etch process for forming the trenches is performed under conditions including a chamber pressure ranging from approximately 30 mTorr to approximately 50 mTorr, a RF power ranging from approximately 1,000 W to approximately 2,000 W, a bias power ranging from approximately 1,500 W to approximately 2,500 W, and etch gases including C₄F₆, O₂, tetrafluoromethane (CF₄), and Ar, in consideration of an etch rate of the insulation layer including the HDP oxide layer. The C₄F₆, O₂, CF₄, and Ar gases flow at a rate ranging from approximately 30 sccm to approximately 50 sccm, from approximately 10 sccm to approximately 50 sccm, from approximately 10 sccm to approximately 30 sccm, and from approximately 500 sccm to approximately 800 sccm, respectively. The temperature in the chamber ranges from about 40° C. to about 60° C. A chamber seasoning is performed to stabilize an atmosphere in the chamber before forming the trenches.

A barrier metal 12 is formed over the surface profile of the patterned insulation layer 11 including the trenches to reduce tungsten diffusion into the patterned insulation layer 11. For example, the barrier metal 12 includes a stacked layer comprising titanium (Ti)/titanium nitride (TiN) formed to have a thickness ranging from approximately 30 Å to approximately 100 Å.

A conductive material is formed over the barrier metal 12 and fills in the trenches. The conductive material may include a tungsten layer, a copper layer, an aluminum layer, or a conductive polysilicon layer. For example, a tungsten layer 13 may be formed over the barrier metal 12. The tungsten layer 13 is formed to have a thickness ranging from approximately 3,000 Å to approximately 10,000 Å in consideration of a subsequent CMP process.

As shown in FIG. 1B, the tungsten layer 13 (referring to FIG. 1A) is polished by performing a chemical mechanical polishing (CMP) process 14. Therefore, planarized bit lines 13A are formed. In general, a CMP process is performed as described below. When a surface of the tungsten layer 13 and a slurry come in contact, a tungsten oxide layer is formed. The tungsten oxide layer is chemically combined with abrasive particles in the slurry. When a physical force is applied to the abrasive particles, the tungsten oxide layer is removed from the surface of the tungsten layer 13. Impurities 15 remain after the CMP process 14 is performed.

The CMP process 14 is performed under certain conditions in consideration of a polishing rate and a polishing unevenness. For example, a pressurized chamber pressure, a retainer ring pressure, a main air bag condition pressure, and a center air bag pressure each range from approximately 100 hPa to approximately 300 hPa. A top ring velocity ranges from approximately 30 rpm to approximately 100 rpm, a turn table velocity ranges from approximately 30 rpm to approximately 200 rpm, and a slurry flow rate ranges from approximately 100 ml/min to approximately 300 ml/min. A dresser down force ranges from approximately 50 newtons to approximately 100 newtons, a dresser time ranges from approximately 5 seconds to approximately 60 seconds, a dresser velocity ranges from approximately 10 rpm to approximately 100 rpm, and a polisher including colloidal silica having a density of approximately 1 wt % to approximately 10 wt % is used.

However, the imperfect tungsten oxide layer still remains over the planarized bit lines 13A after the CMP process 14 is performed. Therefore, the impurities 15 including abrasives and slurry residue are adsorbed to the tungsten oxide layer and may contaminate the surface of the wafer.

Referring to FIG. 1C, a cleaning process 16 is performed to remove the contamination sources. The cleaning process 16 uses a buffered oxide etchant (BOE) solution added with an organic acid. In other words, a mixed cleaning solution is used. The BOE solution may be diluted with deionized (DI) water (H₂O). For example, H₂O and the BOE solution are mixed at a ratio of approximately 100 to 200:1.

In general, the BOE solution includes hydrogen fluoride (HF) and NH₄F mixed at a ratio of approximately 100:1 or approximately 300:1. The HF solution is used for removing the contamination sources. NH₄F is used to maintain the concentration of fluorine (F) in the HF or maintain the overall pH of the BOE solution. The organic acid added to the BOE solution forms a passivation layer over the surface of the planarized bit lines 13A. The passivation layer reduces re-adsorption of the particles desorbed from the wafer surface and decreases oxidation. The concentration of the organic acid ranges from approximately 0.0001 ppm to approximately 100 ppm.

In one embodiment, the organic acid includes acetic acid, aconitic acid, adipic acid, anthranilic acid, arachidic acid, L-ascorbic acid, azelaic acid, citric acid, etidronic acid, formic acid, fumaric acid, D-gluconic acid, humic acid, hydriodic acid, isobutyric acid, lactic acid, lanolin acid, levulinic acid, methacrylic acid, methanesulfonic acid, myreth-5-carboxylic acid, myristic acid, nonanoic acid, nordihydroguairetic acid, oleth-6-carboxylic acid, peracetic acid, perchloric acid, periodic acid, phenolsulfonic acid, propionic acid, sebacic acid, sorbic acid, succinic acid, tannic acid, tartaric acid, L-tartaric acid, O-toluene sulfonic acid, P-toluene sulfonic acid, M-toluic acid, trichloroacetic acid, trifluoromethane sulfonic acid, uric acid, or usnic acid.

In detail, the cleaning process 16 includes cleaning using the BOE solution added with the organic acid, cleaning using H₂O, and cleaning using the BOE solution added with the organic acid. The cleaning using the BOE solution added with the organic acid is performed for approximately 30 seconds to approximately 60 seconds while brushing at a brush station. The cleaning using H₂O is performed for approximately 30 seconds to approximately 60 seconds while brushing at a brush station.

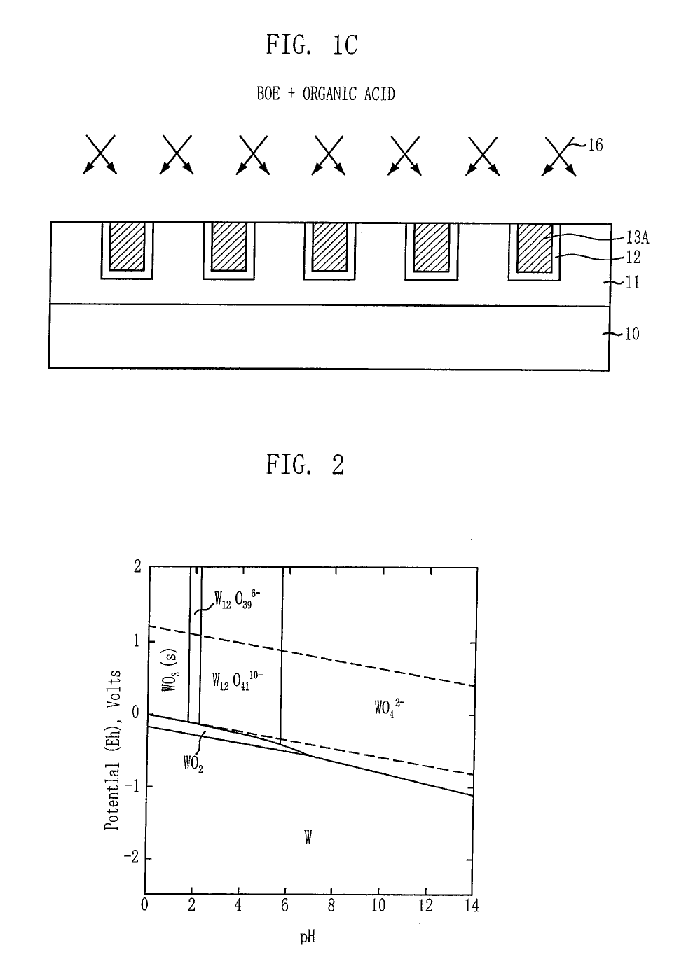

FIG. 2 illustrates a potential-pH equilibrium of a tungsten-water system. A principle for forming the tungsten oxide layer during the CMP process 14 is described. Types of the tungsten oxide layer and corrosion potentials according to different pH levels of the slurry are shown. For example, tungsten trioxide (WO₃) is formed in a pH range between approximately 0 to approximately 2, W₁₂O₃₉⁶⁻ and W₁₂O₄₁¹⁰⁻ are formed in a pH range between approximately 3 to approximately 6, and WO₄²⁻ is formed in a pH range between approximately 6 to approximately 14. In other words, the types of the oxide-based layers generated over the tungsten surface depend on a pH level of the slurry. Typically, the pH level of the slurry used in a tungsten CMP process ranges from approximately 3 to approximately 11. Therefore, imperfect oxide-based layers such as W₁₂O₃₉⁶⁻, W₁₂O₄₁¹⁰⁻, and WO₄²⁻ are formed when the tungsten is exposed to the slurry. Thus, the oxide-based layers react easily to the abrasives in the slurry.

Furthermore, using the BOE solution added with the organic acid may decrease an amount of a cleaner used in a polishing apparatus to improve cleaning efficiency. Also, the cleaning efficiency of the cleaning process may be increased by removing the contamination sources from the surface of the tungsten.

In accordance with an embodiment of the present invention, as the cleaning process uses the BOE solution added with the organic acid, the number of cleaning solutions used decreases compared to the typical method which uses two types of solutions including NH₄ and HF. Therefore, production costs are reduced.

Also, the number of baths for containing the cleaning solution is deceased to one. Accordingly, the amount of a cleaner used in a polishing apparatus is decreased to improve cleaning efficiency.

Furthermore, adding the organic acid reduces re-adsorption of contamination sources to a tungsten surface. As a result, the efficiency of the cleaning process is improved.

While the present invention has been described with respect to specific embodiments, it will be apparent to those skilled in the art that various changes and modifications may be made without departing from the spirit and scope of the invention as defined in the following claims.

What is claimed is:

1. A method for forming a conductive pattern in a semiconductor device, the method comprising:
providing an insulation layer including a trench;
forming a conductive material over the insulation layer, wherein the conductive layer fills in the trench;
polishing the conductive material to expose the insulation layer, wherein the polished conductive layer and the exposed insulation layer form a resultant structure; and
cleaning the resultant structure using a cleaning solution.

2. The method of claim 1, wherein the cleaning solution includes a buffered oxide etchant (BOE) solution added with an organic acid.

3. The method of claim 2, wherein the BOE solution is diluted with H₂O.

4. The method of claim 2, wherein the conductive material comprises one of a tungsten layer, a copper layer, an aluminum layer, and a conductive polysilicon layer.

5. The method of claim 2, wherein the organic acid comprises one selected from a group consisting of: acetic acid, aconitic acid, adipic acid, anthranilic acid, arachidic acid, L-ascorbic acid, azelaic acid, citric acid, etidronic acid, formic acid, fumaric acid, D-gluconic acid, humic acid, hydriodic acid, isobutyric acid, lactic acid, lanolin acid, levulinic acid, methacrylic acid, methanesulfonic acid, myreth-5-carboxylic acid, myristic acid, nonanoic acid, nordihydroguairetic acid, oleth-6-carboxylic acid, peracetic acid, perchloric acid, periodic acid, phenolsulfonic acid, propionic acid, sebacic acid, sorbic acid, succinic acid, tannic acid, tartaric acid, L-tartaric acid, O-toluene sulfonic acid, P-toluene sulfonic acid, M-toluic acid, trichloroacetic acid, trifluoromethane sulfonic acid, uric acid, and usnic acid.

6. The method of claim 2, wherein cleaning the resultant structure comprises:
cleaning the resultant structure using the BOE solution added with the organic acid;
cleaning the resultant structure using H₂O; and
cleaning the resultant structure using the BOE solution added with the organic acid.

7. The method of claim 6, wherein cleaning the resultant structure using the BOE solution added with the organic acid is performed for approximately 30 seconds to approximately 60 seconds while brushing.

8. The method of claim 6, wherein cleaning the resultant structure using the H₂O is performed for approximately 30 seconds to approximately 60 seconds while brushing.

9. The method of claim 2, wherein polishing the conductive material comprises performing a chemical mechanical polishing (CMP) method.

10. The method of claim 9, wherein the CMP process uses colloidal silica as an abrasive in a slurry.

11. The method of claim 9, wherein the CMP process comprises using a pressurized chamber pressure, a retainer ring pressure, a main air bag condition pressure, and a center air bag pressure, wherein each pressure ranges from approximately 100 hPa to approximately 300 hPa.

12. The method of claim 9, wherein the CMP process comprises using a top ring velocity ranging from approximately 30 rpm. to approximately 100 rpm, a turn table velocity ranging from approximately 30 rpm to approximately 200 rpm, and a slurry flow rate ranging from approximately 100 ml/min to approximately 300 ml/min.

13. The method of claim 9, wherein the CMP process comprises using a dresser down force ranging from approximately 50 newtons to approximately 100 newtons, a dresser time ranging from approximately 5 seconds to approximately 60 seconds, and a dresser velocity ranging from approximately 10 rpm to approximately 100 rpm.

14. The method of claim 2, wherein forming the trench comprises:
forming a hard mask pattern including a silicon nitride layer over the insulation layer; and
etching the insulation layer exposed by the hard mask pattern.

15. The method of claim 14, wherein etching the insulation layer comprises using C₄F₆, oxygen O₂, tetrafluoromethane (CF₄), and argon (Ar) gases.

16. The method of claim 14, further comprising, before forming the trench, drying an etch chamber before etching the insulation layer.

17. A method for forming a conductive pattern in a semiconductor device, the method comprising:
forming an insulation layer over a substrate;
forming a trench in the insulation layer;
forming a conductive material over the insulation layer, wherein the conductive layer fills in the trench;
performing a chemical mechanical polishing on the conductive material to expose the insulation layer, wherein the polished conductive layer and the exposed insulation layer form a resultant structure; and
cleaning the resultant structure using a cleaning solution comprising a buffered oxide etchant (BOE) solution added with an organic acid, wherein the organic acid forms a passivation layer over the resultant structure.

18. The method of claim 17, wherein the BOE solution is diluted with H₂O.

19. The method of claim 17, wherein the conductive material comprises one of a tungsten layer, a copper layer, an aluminum layer, and a conductive polysilicon layer.

20. The method of claim 17, wherein cleaning the resultant structure comprises:
cleaning the resultant structure using the BOE solution added with the organic acid;
cleaning the resultant structure using H₂O; and
cleaning the resultant structure using the BOE solution added with the organic acid.

21. The method of claim 17, wherein the chemical mechanical polishing is performed using colloidal silica as an abrasive in a slurry.

22. The method of claim 17, wherein the passivation layer reduces re-adsorption of particles desorbed from the substrate and decreases oxidation.
